(19) United States
(12) Patent Application Publication
(10) Pub. No.: US 2026/0171171 A1
(43) Pub. Date: Jun. 18, 2026

(54) MEMORY DEVICE FOR CONTROLLING VOLTAGES SUPPLIED TO WORD LINES AND OPERATING METHOD OF THE MEMORY DEVICE

(71) Applicant: SAMSUNG ELECTRONICS CO., LTD., Suwon-si (KR)

(72) Inventors: Soochang LEE, Suwon-si (KR); Yonghyuk CHOI, Suwon-si (KR); Doohyun KIM, Suwon-si (KR); Kwangho CHOI, Suwon-si (KR)

(73) Assignee: SAMSUNG ELECTRONICS CO., LTD., Suwon-si (KR)

(21) Appl. No.: 19/331,582

(22) Filed: Sep. 17, 2025

(30) Foreign Application Priority Data
Dec. 13, 2024 (KR) 10-2024-0186167

(51) Int. Cl. G11C 16/34; G11C 16/08; G11C 16/30

(52) U.S. Cl. CPC G11C 16/3404; G11C 16/08; G11C 16/30

(57) ABSTRACT

A memory device includes: a memory cell array including a plurality of cell blocks, each of the plurality of cell blocks including a plurality of main word lines configured to be programmed with data and a ground selection line (GSL) region including a plurality of ground selection lines configured to be coded to be electrically separated on a plurality of cell strings; a control logic configured to control a memory operation on the memory cell array and control a recovery operation of initializing lines in the cell blocks; and a voltage generator configured to generate a recovery voltage provided to the plurality of ground selection lines in the recovery operation. The plurality of ground selection lines may be configured to be programmed to have a first threshold voltage distribution at a first threshold voltage level and a second threshold voltage distribution at a second threshold voltage level.

### CROSS-REFERENCE TO RELATED APPLICATION

This application is based on and claims priority under 35 U.S.C. §119 to Korean Patent Application No. 10-2024-0186167, filed on December 13, 2024, in the Korean Intellectual Property Office, the disclosure of which is incorporated by reference herein in its entirety.

### BACKGROUND

The disclosure relates to a memory device, and more particularly, to a memory device and an operating method thereof, which may control voltages supplied to various word lines included in a cell block.

Non-volatile memory devices include a plurality of memory cells which non-volatilely store data. As an example of non-volatile memory devices, flash memory devices may be used in portable phones, digital cameras, portable digital assistants (PDA), mobile computer devices, stationary computer devices, servers, and various other systems.

Three-dimensional (3D) memory devices including a plurality of vertical channel structures extending in a vertical direction on a substrate have been developed to increase the capacity of memory devices. Each cell block of 3D memory devices may include a plurality of cell strings, and there is a need to separate ground selection lines on the plurality of cell strings in association with a memory operation. In this case, in order to enhance the degree of integration of memory devices, a method has been proposed where, as a dummy hole is formed in a memory device, a ground selection line (GSL) region including a plurality of ground selection lines (for example, coding GSLs) coded to have a certain threshold voltage is provided instead of physically separating ground selection lines, and thus, ground selection lines are electrically separated on a plurality of cell strings.

However, as a memory device performs various operations, a retention characteristic of ground selection lines may be reduced, or a degradation in threshold voltage characteristic caused by hot carrier injection (HCI) may occur, and when a threshold voltage characteristic of a GSL region is degraded, the data reliability of memory devices may be reduced.

### SUMMARY

The disclosure provides a memory device and an operating method thereof, which may decrease or prevent a degradation in threshold voltage characteristic of ground selection lines included in a ground selection line (GSL) region and may enhance the reliability of data.

According to an aspect of the disclosure, a memory device may include: a memory cell array including a plurality of cell blocks, each of the plurality of cell blocks including a plurality of main word lines configured to be programmed with data and a ground selection line (GSL) region including a plurality of ground selection lines configured to be coded to be electrically separated on a plurality of cell strings; a control logic configured to control a memory operation on the memory cell array and control a recovery operation of initializing lines in the cell blocks; and a voltage generator configured to generate a recovery voltage provided to the plurality of ground selection lines in the recovery operation. The plurality of ground selection lines may be configured to be programmed to have a first threshold voltage distribution at a first threshold voltage level and a second threshold voltage distribution at a second threshold voltage level, the second threshold voltage level being higher than the first threshold voltage level, and the control logic may be further configured to control the voltage generator so that a level of the recovery voltage provided to a corresponding ground selection line increases as the second threshold voltage level increases.

According to an aspect of the disclosure, a memory device may include: a memory cell array including a plurality of cell blocks, each of the plurality of cell blocks including a plurality of main word lines configured to be programmed with data and a plurality of ground selection lines configured to be coded to be electrically separated on a plurality of cell strings; and a control logic configured to control a memory operation on the memory cell array and control levels of voltages provided to the plurality of cell blocks. The plurality of ground selection lines may include: a first ground selection line corresponding to a first dummy line, and a second ground selection line on the first ground selection line and configured to be programmed to have threshold voltage distributions based on the coding, the second ground selection line is configured to have a first threshold voltage distribution at a first threshold voltage level and a second threshold voltage distribution at a second threshold voltage level, and the first ground selection line is configured to have a third threshold voltage distribution. A first cell string of the plurality of cell strings may include a first dummy transistor connected to the first ground selection line and configured to have a third threshold voltage level, and a ground selection transistor connected to the second ground selection line and configured to have the first threshold voltage level. The control logic may be further configured to, in a set-up process on voltages provided to the plurality of cell blocks, perform control so that an increase slope of a first voltage provided to the first ground selection line increases, and the first voltage reaches a target level earlier than a second voltage provided to the second ground selection line.

According to an aspect of the disclosure, a memory device may include: a cell block including a ground selection line (GSL) region including a plurality of ground selection lines configured to be coded to be electrically separated on a plurality of cell strings of the cell block; a control logic configured to control a memory operation on the cell block and control a recovery operation of initializing lines in the cell block; and a voltage generator configured to generate a recovery voltage provided to the plurality of ground selection lines in the recovery operation. The plurality of ground selection lines may be configured to be programmed to have a first threshold voltage distribution at a first threshold voltage level and a second threshold voltage distribution at a second threshold voltage level, the second threshold voltage level being higher than the first threshold voltage level, and the control logic may be further configured to control the voltage generator so that a level of the recovery voltage provided to a corresponding ground selection line increases as the second threshold voltage level increases.

According to an aspect of the disclosure, an operating method of a memory device including a plurality of cell blocks each including a plurality of main word lines programmed with data and a ground selection line (GSL) region including a plurality of ground selection lines coded to be electrically separated on a plurality of cell strings, may include: programming each of the plurality of ground selection lines with a first threshold voltage distribution and a second threshold voltage distribution, based on the coding, entering a recovery period after a program or read operation on each of the plurality of cell blocks, and providing a corresponding ground selection line with a recovery voltage where a level thereof increases as a second threshold voltage level of the corresponding ground selection line increases, in the recovery period.

The first threshold voltage level may be lower than the second threshold voltage level, when the first threshold voltage level corresponds to a first value and the second threshold voltage level corresponds to a second value, the recovery voltage may have a first level, and when the first threshold voltage level corresponds to a third value which is less than the first value and the second threshold voltage level corresponds to the second value, the recovery voltage may have a second level which is lower than the first level.

The plurality of cell blocks may include a first cell block and a second cell block, a threshold voltage distribution of the ground selection lines of the first cell block may differ from a threshold voltage distribution of the ground selection lines of the second cell block, and a level of the recovery voltage provided to the ground selection lines of the first cell block may differ from a level of the recovery voltage provided to the ground selection lines of the second cell block.

The GSL region may include a first ground selection line corresponding to a dummy line and programmed to have one threshold voltage distribution, a first cell string of the plurality of cell strings may include a first dummy transistor connected to the first ground selection line and having a third threshold voltage level and a ground selection transistor connected to a second ground selection line disposed on the first ground selection line and having a first threshold voltage level, the second threshold voltage level and the third threshold voltage level may be higher than the first threshold voltage level, and the operating method may further include increasing an increase slope of a first voltage so that the first voltage provided to the first ground selection line earlier reaches a target level than a second voltage provided to the second ground selection line, in a set-up process on each of the plurality of cell blocks.

The GSL region may further include a third ground selection line disposed between the first ground selection line and the second ground selection line, the first cell string may further include a ground selection transistor connected to the third ground selection line and having the second threshold voltage level, and the operating method may further include increasing an increase slope of a third voltage so that the third voltage provided to the third ground selection line earlier reaches a target level than the second voltage, in the set-up process.

### BRIEF DESCRIPTION OF THE DRAWINGS

Embodiments will be more clearly understood from the following detailed description taken in conjunction with the accompanying drawings in which:

FIG. 1 is a block diagram illustrating a memory system according to one or more embodiments;

FIG. 2A is a diagram illustrating an implementation example of a ground selection line (GSL) region;

FIG. 2B is a diagram illustrating an implementation example of a ground selection line (GSL) region;

FIG. 3 is a block diagram illustrating an implementation example of a memory device of FIG. 1;

FIG. 4A is a diagram illustrating an example where a level of a recovery voltage varies based on a threshold voltage distribution of a ground selection line;

FIG. 4B is a diagram illustrating an example where a level of a recovery voltage varies based on a threshold voltage distribution of a ground selection line;

FIG. 5A is a diagram illustrating an example where a level of a recovery voltage varies based on a threshold voltage distribution of a ground selection line;

FIG. 5B is a diagram illustrating an example where a level of a recovery voltage varies based on a threshold voltage distribution of a ground selection line;

FIG. 5C is a diagram illustrating an example where a level of a recovery voltage varies based on a threshold voltage distribution of a ground selection line;

FIG. 6A is a diagram illustrating a case where a plurality of recovery voltage levels are set on a GSL region;

FIG. 6B is a diagram illustrating a case where a plurality of recovery voltage levels are set on a GSL region;

FIG. 7 is a flowchart illustrating an operating method of a memory device, according to one or more embodiments;

FIG. 8 is a diagram illustrating a channel potential of a cell string in association with the control of a voltage slope, according to one or more embodiments;

FIG. 9A is a diagram illustrating a channel potential occurring in a set-up process when one or more embodiments is not applied;

FIG. 9B is a diagram illustrating a channel potential occurring in a set-up process when one or more embodiments is not applied;

FIG. 10A is a diagram illustrating a channel potential occurring in a set-up process when one or more embodiments is applied;

FIG. 10B is a diagram illustrating a channel potential occurring in a set-up process when one or more embodiments is applied;

FIG. 11A is a diagram illustrating a channel potential occurring in a set-up process when one or more embodiments is applied;

FIG. 11B is a diagram illustrating a channel potential occurring in a set-up process when one or more embodiments is applied;

FIG. 12 is a diagram illustrating a channel potential occurring in a set-up process when one or more embodiments is applied;

FIG. 13A is a perspective view illustrating a cell block according to one or more embodiments;

FIG. 13B is a perspective view illustrating a cell block according to one or more embodiments; and

FIG. 14 is a block diagram illustrating a storage device to which a memory device according to one or more embodiments is applied.

### DETAILED DESCRIPTION

Hereinafter, embodiments will be described in detail with reference to the accompanying drawings.

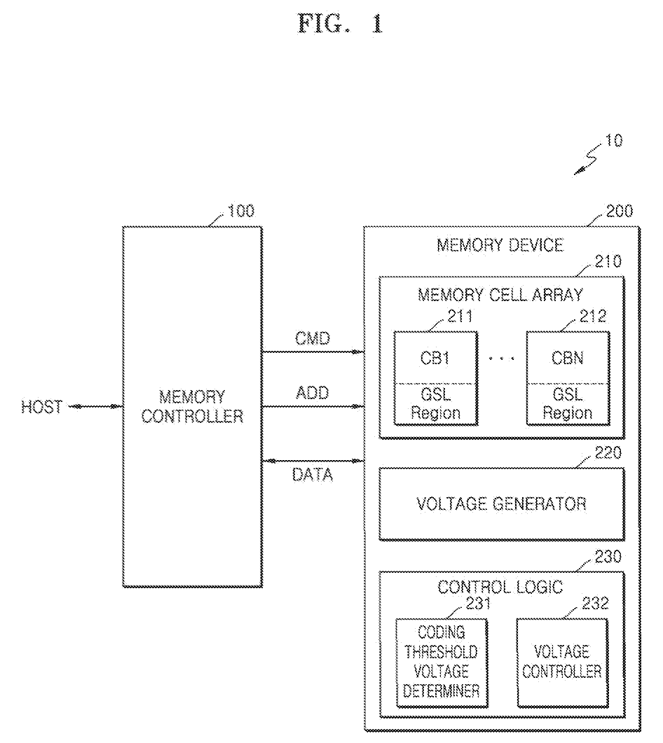

FIG. 1 is a block diagram illustrating a memory system 10 according to one or more embodiments.

Referring to FIG. 1, the memory system 10 may include a memory controller 100 and a memory device 200, and the memory device 200 may include a memory cell array 210, a voltage generator 220, and a control logic 230. The memory device 200 may further include various elements associated with a memory operation such as programming/reading/erasing of data.

According to one or more embodiments, the memory device 200 may include a non-volatile memory device. For example, the memory device 200 may include a non-volatile memory device such as NAND flash memory, vertical NAND flash memory, resistive random access memory (RRAM), phase-change memory, or magnetoresistive random access memory (MRAM). In one or more embodiments, the memory device 200 or the memory system 10 may be implemented as an embedded memory embedded in an electronic device, or may be implemented as an external memory detachably attached to an electronic device. For example, the memory device 200 or the memory system 10 may be implemented as various types such as a universal flash storage (UFS) memory device, an embedded multimedia card (eMMC), a solid state drive (SSD), a UFS memory card, a compact flash (CF) card, a secure digital (SD) card, a micro secure digital (micro-SD) card, a mini secure digital (mini-SD) card, an extreme digital (xD) card, and a memory stick. The memory system 10 may be referred to as a storage device or a storage system, in terms of non-volatilely storing data.

The memory controller 100 may control the memory device 200 to read data stored in the memory device 200 or program data in the memory device 200, in response to a write/read request from a host HOST. In detail, the memory controller 100 may provide an address ADD and a command CMD to the memory device 200 and may thus control program, read, and erase operations on the memory device 200. Also, data DATA to be written in the memory device 200 and the data DATA read from the memory device 200 may be transferred and received between the memory controller 100 and the memory device 200.

The memory cell array 210 may include a plurality of cell blocks. When the memory device 200 corresponds to a vertical NAND flash memory device, each of the plurality of cell blocks may include a plurality of cell strings. For example, a plurality of cell strings may be disposed to correspond to one bit line, and in a data program/read operation, one cell string selected from among a plurality of cell strings may be electrically connected to a bit line. Also, ground selection lines may be separated from each other on a plurality of cell strings, and for example, ground selection lines may be electrically separated from each other on a plurality of cell strings, based on coded ground selection lines.

Each of the cell blocks may include a coded ground selection line region where a plurality of coded ground selection lines are disposed. In describing the following embodiments, the coded ground selection line region may be referred to as a GSL region. Also, the coded ground selection line may be a line which is included in the GSL region and on which coding is performed, and in one or more embodiments, the coded ground selection line may be referred to as a ground selection line or a coded ground selection line. Also, some of ground selection lines may be used as a dummy line which is programmed with one threshold voltage, and coded ground selection lines of the ground selection lines may be defined as a concept distinguished from the dummy line.

Also, the cell block may further include at least one ground selection line which is disposed in a lower portion of the GSL region and is disposed on a plurality of cell strings in common. In the following embodiments, a ground selection line disposed outside the GSL region may be an element distinguished from the ground selection line of the GSL region and may be referred to as a common ground selection line (a common GSL).

The cell block may include a plurality of word lines connected to a plurality of transistors which are vertically disposed in a cell string. The word lines may be defined as a concept including various kinds of lines, and for example, the word lines may include a string selection line, a main word line, the ground selection line of the GSL region, a common GSL, and the other lines. As examples of the other lines, a common dummy line and at least one erase control line (for example, a gate induced drain leakage (GIDL) line) each disposed at an arbitrary position outside the GSL region may be included in a cell block. The erase control line may cause GIDL and may be disposed for enhancing an erase characteristic of a cell block, and for example, an erase voltage may be provided to a channel through transistors connected to the erase control line. Also, a plurality of transistors may include a string selection transistor, memory cells, a ground selection transistor, a common ground selection transistor, and a dummy cell.

A plurality of ground selection transistors may be respectively connected to each ground selection line of the GSL region, and as coding is performed on the GSL region, the ground selection transistors may be programmed with a certain threshold voltage. For example, some of a plurality of ground selection transistors connected to one ground selection line may be programmed at a first threshold voltage level and may thus have a first threshold voltage distribution, and the other ground selection transistors may be programmed at a second threshold voltage level and may thus have a second threshold voltage distribution. Here, the second threshold voltage level may be higher than the first threshold voltage level. When each of the first threshold voltage distribution and the second threshold voltage distribution has a program state, programming may be performed on all of a plurality of ground selection transistors connected to one ground selection line in a coding process. Alternatively, when the first threshold voltage distribution corresponds to an erase state, ground selection transistors coded with the first threshold voltage distribution among ground selection transistors connected to one ground selection line may not be programmed in a coding process.

As an implementation example, at least one of a plurality of ground selection lines of the GSL region may be used as a dummy line. For example, ground selection transistors connected to a ground selection line used as a dummy line may be programmed with one threshold voltage. The dummy line may be disposed for enhancing a channel potential boundary characteristic between the GSL region and external lines thereof, or may be disposed for enhancing a channel potential boundary characteristic between lines of the GSL region. For example, the dummy line may be disposed at various positions of the GSL region so as to enhance a retention characteristic or a hot carrier injection (HCI) characteristic of various lines.

As an implementation example, when a structure where a common source line CSL, a common ground selection line, a GSL region, and a plurality of main word lines are sequentially arranged in a vertical direction from a substrate is assumed, a dummy line may be disposed in a lower portion of the GSL region and may thus be disposed adjacent to the common source line CSL (or the common ground selection line). Alternatively, the dummy line may be disposed in an upper portion of the GSL region and may thus be disposed adjacent to the plurality of main word lines. Alternatively, the dummy line may be disposed at an arbitrary position between ground selection lines. Also, the GSL region may include two or more dummy lines, and thus, dummy lines may be disposed at various positions of the GSL region.

Furthermore, the memory device 200 may perform various memory operations such as data program, read, and erase operations, and for example, may perform a set-up operation of varying various voltages, provided to word lines, to a target level in association with a memory operation and a recovery operation of applying a voltage of a certain low level to the word lines to initialize the word lines after the memory operation ends.

For example, voltages provided to word lines in a set-up period may increase to a target level with a certain slope. For example, a first voltage having a relatively low level or a second voltage having a relatively high level may be provided to each ground selection line which are programmed with first and second threshold voltage distributions in the GSL region, based on a coding pattern. Also, a third voltage may be provided to the dummy line of the GSL region, and a fourth voltage may be provided to the other word lines (for example, the common GSL and the erase control line) disposed outside the GSL region. Also, in a recovery period, a recovery voltage may be provided to the ground selection lines of the GSL region, and for example, the recovery voltage may have a level between the first threshold voltage and the second threshold voltage.

The first threshold voltage and the second threshold voltage of the ground selection line may have various levels. For example, coding information associated with coding of the GSL region may be included in the memory controller 100 and/or the memory device 200, and in initial driving or operation environment setting of the memory device 200, the memory controller 100 may program the ground selection lines of the GSL region with a threshold voltage distribution of a certain level, based on the coding information.

In one or more embodiments, in initial driving or operation environment setting of the memory device 200 described above, a level of the recovery voltage may be set based on threshold voltage levels of the GSL region. For example, based on control by the memory controller 100 or the memory device 200, information representing a level of the recovery voltage may be set in the memory device 200 according to the coding information and/or a coding result of the GSL region, and as the memory device 200 enters the recovery period, the memory device 200 may perform a control operation so that the recovery voltage having the set level is provided to the GSL region.

For example, the level of the recovery voltage provided to ground selection lines may be differently set based on threshold voltage levels of the ground selection lines. For example, when a recovery voltage level is lower than a second threshold voltage level, a retention characteristic may be degraded as electrons of ground selection transistors having the second threshold voltage distribution are leaked, and particularly, when the second threshold voltage level is high, a retention characteristic may be further degraded. Also, when the recovery voltage level is high, ground selection transistors having the first threshold voltage distribution may be affected by interference causing an increase in threshold voltage level.

Memory cells connected to a main word line may have first to Nth distributions based on data program, and in one or more embodiments, each of the first and second threshold voltage distributions of the ground selection line may correspond to one of the first to Nth distributions. In this case, when the second threshold voltage distribution corresponds to the Nth distribution, a threshold voltage level may be high, and thus, the possibility that the retention characteristic described above degrades may be high. Also, when the first threshold voltage distribution corresponds to the first distribution, a threshold voltage level may be low, and thus, a risk based on the interference may be relatively large.

Also, in a case where voltages provided to word lines are set in a memory operation such as program and read operations, potentials of channels corresponding to word lines of a cell block may differ, and due to this, a threshold voltage characteristic of the GSL region may be degraded due to HCI. For example, an HCI risk may largely occur in a period where a potential of a channel rapidly varies along an upper position (for example, a position at which a common source line is disposed) of a cell block from a lower position (for example, a position at which a string selection line is disposed) of the cell block, or in a period where a slope of a channel potential is large, and when a potential rapidly varies in a channel corresponding to the GSL region, a threshold voltage characteristic of ground selection lines may be degraded.

In one or more embodiments, as a voltage level provided to the ground selection lines of the GSL region is controlled in the set-up period, the rapid variation of the channel potential may be reduced or prevented, and thus, an HCI risk of the ground selection lines may be reduced or removed. For example, in a cell string, when a threshold voltage level of a ground selection transistor connected to a first ground selection line is high, or a threshold voltage level of a ground selection transistor connected to a second ground selection line disposed on the first ground selection line is low, an HCI risk may occur in a ground selection transistor connected to the second ground selection line in the set-up period. In one or more embodiments, an increase slope of a voltage provided to the first ground selection line may be largely set in the set-up period, and thus, a channel potential corresponding to the first ground selection line may increase. Therefore, a potential difference between a channel corresponding to the first ground selection line and a channel corresponding to the second ground selection line may decrease, and thus, an HCI risk occurring in the second ground selection line may be reduced or removed.

According to one or more embodiments illustrated in FIG. 1, the control logic 230 may include a coding threshold voltage determiner 231 and a voltage controller 232. A coding threshold voltage may include a level and a pattern of a threshold voltage based on coding of the GSL region, and the coding threshold voltage determiner 231 may determine a threshold voltage level and pattern based on a coding result of the ground selection lines of the GSL region. The voltage controller 232 may control a level of the recovery voltage based on a determination result and may control an increase slope or a level of each of various voltages provided to the GSL region in the set-up period. In one or more embodiments, the coding threshold voltage determiner 231 may determine a coding threshold voltage of the GSL region based on coding information associated with coding of the GSL region and may provide the voltage controller 232 with information associated with the determined coding threshold voltage. For example, the information associated with the coding threshold voltage may be set in initial driving or operation environment setting of the memory device 200.

It may be needed to secure a threshold voltage characteristic of the GSL region so as to enhance the electrical separation performance of ground selection lines on cell strings in association with a memory operation. According to one or more embodiments, levels of various voltages provided to the ground selection lines of the GSL region may be controlled in a recovery operation or a set-up process, and based thereon, a retention characteristic of the GSL region may be enhanced, and an HCI risk may decrease, thereby enhancing the reliability of data.

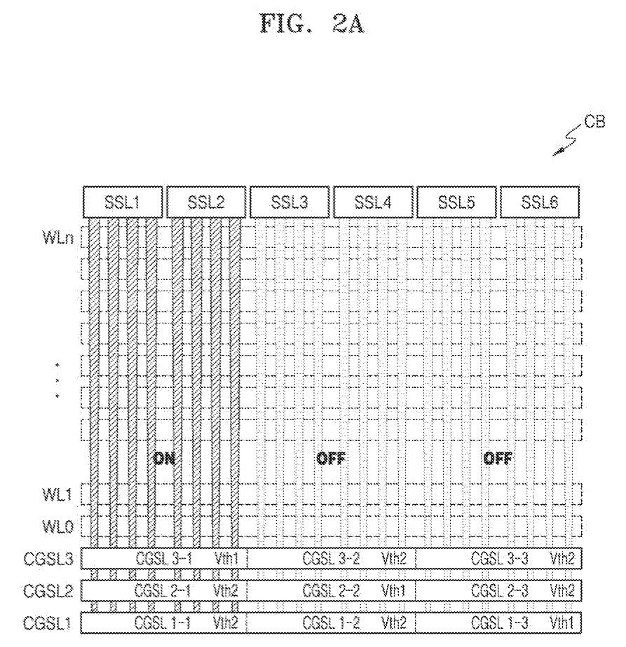

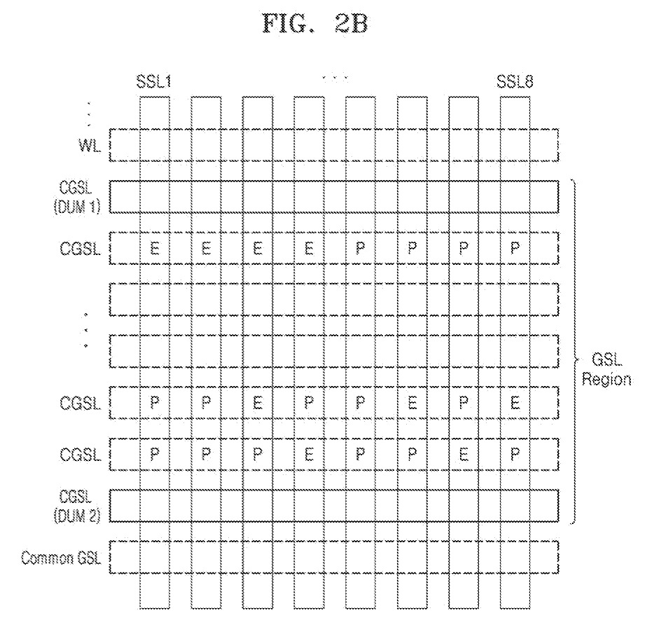

FIGS. 2A and 2B are diagrams illustrating implementation examples of a GSL region.

In a case where ground selection lines are physically separated from each other on each cell string, it may be needed to form a dummy hole for separating the ground selection lines, causing a reduction in degree of integration of a memory device. On the other hand, referring to FIG. 2A, instead of removing the dummy hole, a GSL region may be included in a cell block so as to electrically separate ground selection lines. In one or more embodiments of FIG. 2A, a case where the GSL region includes first to third ground selection lines CGSL1 to CGSL3 is illustrated based on first to sixth string selection lines SSL1 to SSL6. In FIG. 2A, it is illustrated by a dashed line that each ground selection line includes three regions, but this is for conceptually illustrating an electrical separation characteristic, and each of the first to third ground selection lines CGSL1 to CGSL3 may correspond to one line disposed in common in the first to sixth string selection lines SSL1 to SSL6 physically.

Ground selection transistors respectively connected to the first to third ground selection lines CGSL1 to CGSL3 may be programmed with a certain threshold voltage. For example, in association with the third ground selection line CGSL3, ground selection transistors of a third-1 region CGSL3-1 corresponding to the first and second string selection lines SSL1 and SSL2 may be programmed with a first threshold voltage Vth1. On the other hand, ground selection transistors of a third-2 region CGSL3-2 and a third-3 region CGSL3-3 corresponding to the third to sixth string selection lines SSL3 to SSL6 may be programmed with a second threshold voltage Vth2, which is higher than the first threshold voltage Vth1.

Similarly, in association with the second ground selection line CGSL2, ground selection transistors of a second-2 region CGSL2-2 corresponding to the third and fourth string selection lines SSL3 and SSL4 may be programmed with the first threshold voltage Vth1. On the other hand, ground selection transistors of a second-1 region CGSL2-1 and a second-3 region CGSL2-3 corresponding to the first and second string selection lines SSL1 and SSL2 and the fifth and sixth string selection lines SSL5 and SSL6 may be programmed with the second threshold voltage Vth2. Also, in association with the first ground selection line CGSL1, ground selection transistors of a first-3 region CGSL1-3 corresponding to the fifth and sixth string selection lines SSL5 and SSL6 may be programmed with the first threshold voltage Vth1, and ground selection transistors of a first-1 region CGSL1-1 and a first-2 region CGSL1-2 corresponding to the first to fourth string selection lines SSL1 to SSL4 may be programmed with the second threshold voltage Vth2.

When one of the first and second string selection lines SSL1 and SSL2 is selected, a ground selection voltage having a level between the first threshold voltage and the second threshold voltage may be provided to the third ground selection line CGSL3, and thus, the ground selection transistors of the third-1 region CGSL3-1 may be turned on, and the ground selection transistors of the third-2 region CGSL3-2 and the third-3 region CGSL3-3 may be turned off. Accordingly, cell strings of the third to sixth string selection lines SSL3 to SSL6 may be electrically separated from a common source line.

Also, when one of the third and fourth string selection lines SSL3 and SSL4 is selected, a ground selection voltage having a level between the first threshold voltage and the second threshold voltage may be provided to the second ground selection line CGSL2, and thus, the ground selection transistors of the second-2 region CGSL2-2 may be selectively turned on. Also, when one of the fifth and sixth string selection lines SSL5 and SSL6 is selected, a ground selection voltage having a level between the first threshold voltage and the second threshold voltage may be provided to the first ground selection line CGSL1, and thus, the ground selection transistors of the first-3 region CGSL1-3 may be selectively turned on.

In one or more embodiments of FIG. 2A, a case is illustrated where three ground selection lines are disposed on the first to sixth string selection lines SSL1 to SSL6, and thus, ground selection lines are electrically separated from each other by units of two cell strings. However, the GSL region may be variously implemented, and for example, as a various number of ground selection lines are included in the GSL region, ground selection lines may be electrically separated from each other by units of a various number of cell strings.

FIG. 2B illustrates another implementation example of a GSL region.

As illustrated in FIG. 2B, a GSL region may include a plurality of ground selection lines CGSL, the plurality of ground selection lines CGSL may include a first dummy line Dum1 and a second dummy line Dum2 and may also include ground selection lines CGSL therebetween the first dummy line Dum1 and the second dummy line Dum2. Dummy cells of each of the first dummy line Dum1 and the second dummy line Dum2 may have one threshold voltage distribution. Also, the ground selection lines CGSL therebetween the first dummy line Dum1 and the second dummy line Dum2 may be referred to as a coding region where coding is performed, and ground selection transistors connected to the ground selection line CGSL of the coding region may have a first threshold voltage distribution and a second threshold voltage distribution. For example, in FIG. 2B, the first threshold voltage is illustrated in an erase state E, and the second threshold voltage is illustrated in a program state P.

The ground selection transistors may be turned on or off based on a level of a voltage provided to the ground selection lines CGSL. For example, when a voltage having a level between the first threshold voltage and the second threshold voltage is provided to the ground selection line CGSL, a ground selection transistor programmed with the first threshold voltage may be turned on, and a ground selection transistor programmed with the second threshold voltage may be turned off. For example, a voltage level provided to the ground selection lines CGSL may be controlled, and thus, all ground selection transistors of a selection cell string may be turned on. On the other hand, in unselected cell strings, at least one ground selection transistor may be turned off.

Furthermore, as illustrated in FIG. 2B, at least one ground selection line CGSL of the GSL region may be used as a dummy line, and for example, the first dummy line Dum1 adjacent to a main word line WL and the second dummy line Dum2 adjacent to a common GSL are illustrated. A plurality of dummy cells (or dummy transistors) connected to each of the first dummy line Dum1 and the second dummy line Dum2 may be programmed with a certain threshold voltage, and for example, the dummy cells may be programmed to have a threshold voltage level between the first threshold voltage and the second threshold voltage. Alternatively, the dummy cells may be programmed at a threshold voltage level corresponding to the second threshold voltage.

Furthermore, in addition to the word lines illustrated in FIG. 2B, various kinds of lines may be further provided in a cell block, and for example, at least one common dummy line and at least one erase control line (or GIDL line) each disposed outside the GSL region may be further provided. The erase control line may cause GIDL and may be disposed for enhancing an erase characteristic of a cell block, and for example, an erase voltage may be provided to a channel through transistors connected to the erase control line.

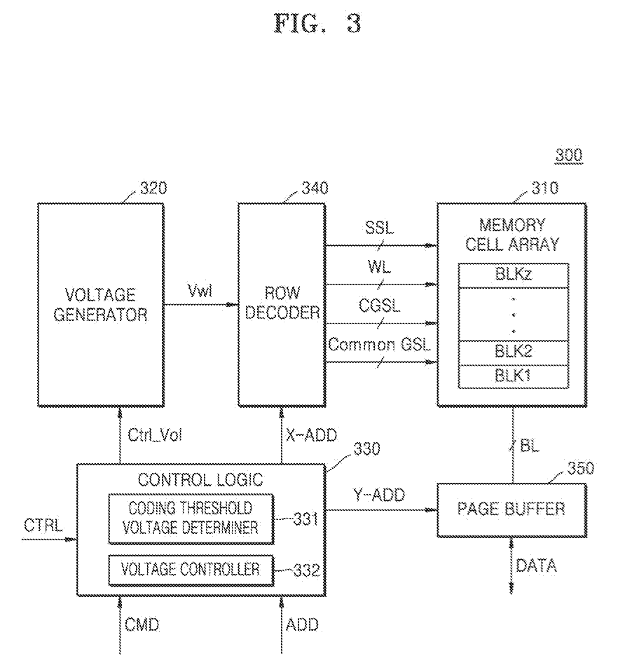

FIG. 3 is a block diagram illustrating an implementation example of the memory device 200 of FIG. 1.

Referring to FIG. 3, a memory device 300 may include a memory cell array 310, a voltage generator 320, a control logic 330, a row decoder 340, and a page buffer 350. The memory device 300 may further include various other elements, associated with a memory operation, such as a data input/output (I/O) circuit or an I/O interface.

The memory cell array 310 may include a plurality of cell blocks BLK1 to BLKz. Also, the row decoder 340 may be connected to each cell block through word lines, and the word lines may include main word lines WL, string selection lines SSL, ground selection lines CGSL of a GSL region, and at least one common GSL. Also, the page buffer 350 may be connected to each cell block through bit lines BL. Each of memory cells may store one or more bits, and for example, each memory cell may correspond to one of a multi-level cell (MLC), a triple level cell (TLC), and a quadraple level cell (QLC).

The control logic 330 may output various internal control signals for programming data in the memory cell array 310 or reading data from the memory cell array 310, based on a command CMD, an address ADD, and a control signal CTRL each received from a memory controller. For example, the control logic 330 may provide a row address X-ADD to the row decoder 340 and may provide a column address Y-ADD to the page buffer 350. Also, the voltage generator 320 may generate various voltages used in the memory device 300, and for example, may generate a word line voltage Vwl provided to word lines.

The control logic 330 may output a voltage control signal Ctrl_vol for controlling a level of the word line voltage Vwl generated by the voltage generator 320. According to one or more embodiments, the control logic 330 may include a coding threshold voltage determiner 331 and a voltage controller 332, and the voltage controller 332 may output the voltage control signal Ctrl_vol, based on a threshold voltage level and pattern of a ground selection line. In FIG. 3, the coding threshold voltage determiner 331 is illustrated as being included in the control logic 330, but embodiments are not limited thereto and the coding threshold voltage determiner 331 may be provided outside the control logic 330.

In one or more embodiments, the voltage generator 320 may control a level of a recovery voltage provided to a ground selection line CGSL in a recovery period, based on the voltage control signal Ctrl_vol. For example, based on first and second threshold voltage levels of the ground selection line CGSL, the voltage generator 320 may generate the word line voltage Vwl where a level thereof has increased or decreased.

Also, the voltage generator 320 may control a slope of a voltage provided to the ground selection line CGSL in a set-up period, based on the voltage control signal Ctrl_vol. For example, based on a threshold voltage pattern of ground selection transistors disposed adjacent to a cell string, a threshold voltage of a ground selection transistor disposed in a relatively lower portion (or disposed at a common source line side) may be higher than a threshold voltage of an upper ground selection transistor, and a control operation may be performed so that an increase slope of a voltage provided to a ground selection line disposed in a lower portion increases.

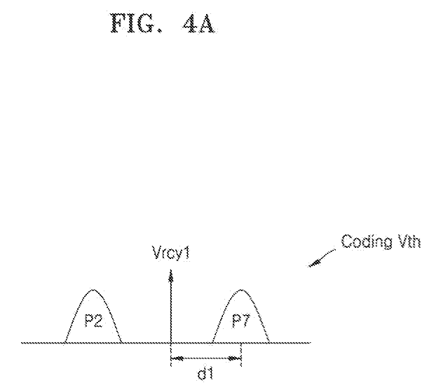

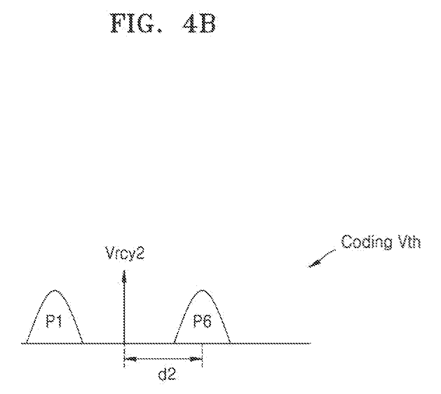

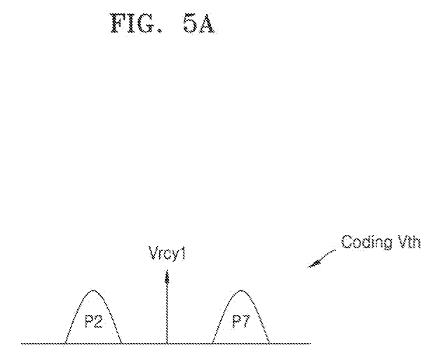

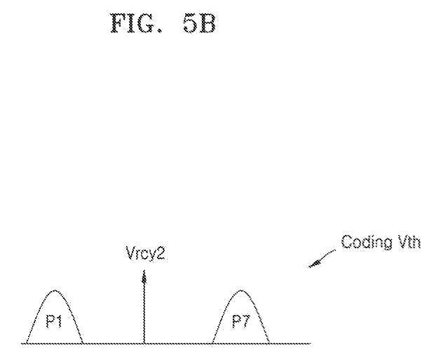

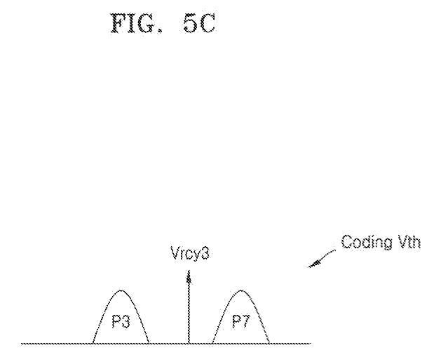

FIGS. 4 and 5 are diagrams illustrating an example where a level of a recovery voltage varies based on a threshold voltage distribution of a ground selection line. A threshold voltage level of a ground selection line may have an arbitrary value, based on coding, and in one or more embodiments of FIGS. 4 and 5, it may be assumed that each memory cell stores data of 3 bits, and thus, the memory cells have an erase state and first to seventh program states P1 to P7, and a threshold voltage distribution of the ground selection line corresponds to a state selected from among the first to seventh program states P1 to P7.

In the related art, a ground voltage or an internal source voltage IVC of a certain level may be fixed and provided to a ground selection line in a recovery operation, and according to embodiments, a level of a recovery voltage provided to the ground selection line may vary based on a level(s) of a first threshold voltage and/or a second threshold voltage.

Referring to FIGS. 4 A-B, a case is illustrated where a threshold voltage distribution of a ground selection line includes a first threshold voltage distribution corresponding to the second program state P2 and a second threshold voltage distribution corresponding to the seventh program state P7, and because the seventh program state P7 is relatively high in threshold voltage level, ground selection transistors having the second threshold voltage distribution may degrade in retention characteristic. In this case, in one or more embodiments illustrated in FIG. 4A, a level of a first recovery voltage Vrcy1 applied to a ground selection line may increase, and thus, a difference d1 between the first recovery voltage Vrcy1 and the second threshold voltage level may decrease, and ground selection transistors having the second threshold voltage distribution may prevent a degradation in retention characteristic.

Moreover, in one or more embodiments illustrated in FIG. 4B, a second recovery voltage Vrcy2 which is set when the first threshold voltage distribution of the ground selection line corresponds to the first program state P1 and the second threshold voltage distribution corresponds to the sixth program state P6 is illustrated, and a second recovery voltage Vrcy2 may be lower than the first recovery voltage Vrcy1. For example, the sixth program state P6 may be lower in threshold voltage level than the seventh program state P7, and thus, a retention characteristic may be less sensitive, whereby a level of the second recovery voltage Vrcy2 may be set to be low.

Also, because the first program state P1 is relatively low in threshold voltage level, interference where a threshold voltage level of a ground selection transistor programmed at a first threshold voltage level increases may occur when a recovery voltage of a high level is applied, and as a level of the second recovery voltage Vrcy2 is lowered, a difference between the second recovery voltage Vrcy2 and the first threshold voltage level may be reduced. For example, a difference d2 between the second recovery voltage Vrcy2 and the first threshold voltage level illustrated in FIG. 4B may be greater than the difference d1 between the first recovery voltage Vrcy1 and the second threshold voltage level illustrated in FIG. 4A.

In FIGS. 5 A-C, one or more embodiments may be described where, when the second threshold voltage level is constant, as the first threshold voltage level varies, a level of a recovery voltage varies.

For example, when the first threshold voltage distribution corresponds to the second program state P2 and the second threshold voltage distribution corresponds to the seventh program state P7 as illustrated in FIG. 5A, a ground selection line of the first recovery voltage Vrcy1 having a level as in one or more embodiments of FIG. 4A may be provided to a ground selection line.

When the first threshold voltage distribution corresponds to the first program state P1 as illustrated in FIG. 5B, a level of the second recovery voltage Vrcy2 may be set to be lower than that of the first recovery voltage Vrcy1, so as to decrease interference occurring in a ground selection transistor programmed at the first threshold voltage level. That is, when the second threshold voltage level is constant, as the first threshold voltage level is lowered, a level of the recovery voltage may be set to be low. Also, when the first threshold voltage distribution corresponds to the third program state P3 as illustrated in FIG. 5C, because a ground selection transistor programmed at the first threshold voltage level is less affected by interference, a level of a third recovery voltage Vrcy3 may be set to be higher than that of the first recovery voltage Vrcy1. That is, when the second threshold voltage level is constant, as the first threshold voltage level increases, a level of the recovery voltage may be set to be high.

According to one or more embodiments described above, a level of the recovery voltage may be optimally set based on the first and second threshold voltage levels of the GSL region, and thus, a margin between the first threshold voltage distribution and the second threshold voltage distribution may be sufficiently secured in the ground selection line of the GSL region, and an electrical separation characteristic of the GSL region may be secured, thereby enhancing the reliability of data of a memory device.

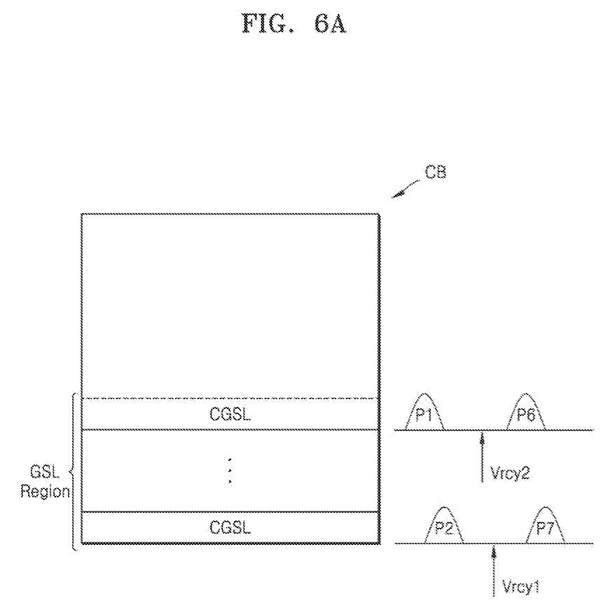

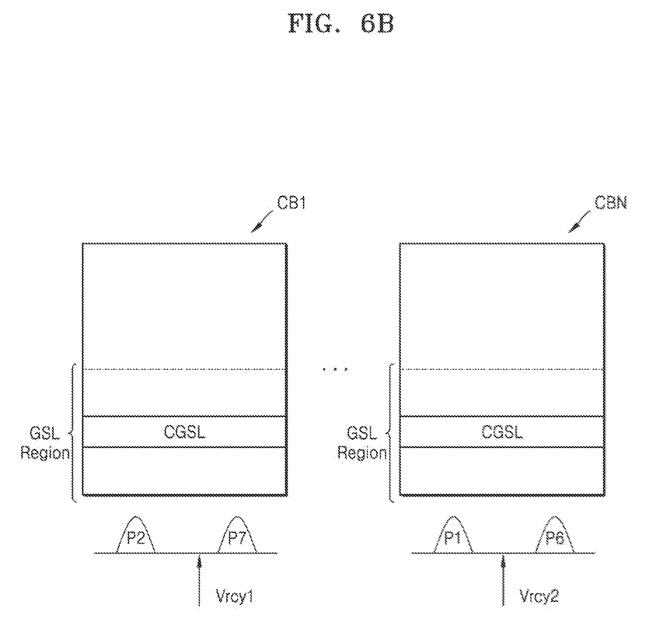

FIGS. 6A and 6B are diagrams illustrating a case where a plurality of recovery voltage levels are set on a GSL region.

Referring to FIG. 6A, one cell block CB may include a GSL region, and the GSL region may include a plurality of ground selection lines CGSL. According to one or more embodiments described above, the ground selection lines CGSL may be coded based on various methods, and thus, may have arbitrary threshold voltage distributions. For example, in the GSL region, a case may be assumed where one ground selection line (for example, a first ground selection line) has a first threshold voltage distribution corresponding to a second program state P2 and a second threshold voltage distribution corresponding to a seventh program state P7, and the other ground selection line (for example, a second ground selection line) has a first threshold voltage distribution corresponding to a first program state P1 and a second threshold voltage distribution corresponding to a sixth program state P6. In this case, as in one or more embodiments described above, a first recovery voltage Vrcy1 provided to a first ground selection line may have a level which is higher than that of a second recovery voltage Vrcy2 provided to a second ground selection line.

According to one or more embodiments described above, when threshold voltage characteristics of some ground selection lines differ as a plurality of ground selection lines CGSL are programmed with an arbitrary threshold voltage distribution in the same cell block CB, at least two recovery voltage levels may be set on the plurality of ground selection lines CGSL in the same cell block CB.

Referring to FIG. 6B, a case is illustrated where a memory device may include a plurality of cell blocks, and GSL regions may have different threshold voltage characteristics in a first cell block CB1 and an Nth cell block CBN. For example, a ground selection line CGSL in a GSL region of the first cell block CB1 may be coded to have a first threshold voltage distribution corresponding to a second program state P2 and a second threshold voltage distribution corresponding to a seventh program state P7. On the other hand, a ground selection line CGSL in a GSL region of the Nth cell block CBN may be coded to have a first threshold voltage distribution corresponding to a first program state P1 and a second threshold voltage distribution corresponding to a sixth program state P6. In this case, as in one or more embodiments described above, a first recovery voltage Vrcy1 provided to ground selection lines CGSL of the first cell block CB1 may have a level which is higher than that of a second recovery voltage Vrcy2 provided to ground selection lines CGSL of the Nth cell block CBN.

According to one or more embodiments described above, the memory device may include a plurality of cell blocks, coding of GSL regions of some cell blocks may be differently performed, and a recovery voltage having a level set by optimizing a threshold voltage characteristic of a GSL region of each cell block may be provided to a ground selection line CGSL, and thus, the threshold voltage characteristic of the GSL region of each cell block may be maintained well, and the reliability of data may be enhanced.

The memory device may be defined as a concept including a plurality of NAND memories, and each of the plurality of NAND memories may include a plurality of cell blocks. In one or more embodiments, in the memory device, coding of ground selection lines CGSL may be differently applied by NAND memory units, and in this case, a level of a recovery voltage provided to the ground selection line CGSL may be set by NAND memory units.

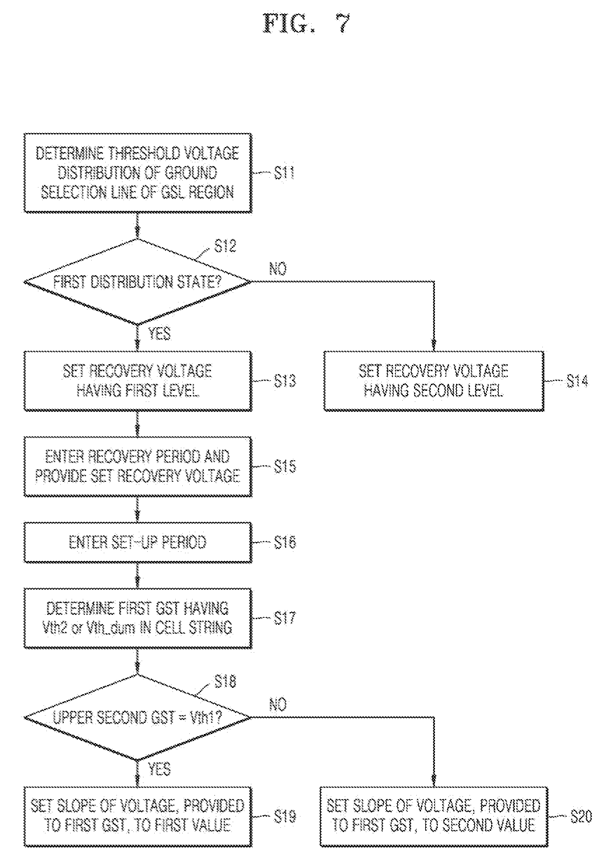

FIG. 7 is a flowchart illustrating an operating method of a memory device, according to one or more embodiments.

Referring to FIG. 7, an operation environment of a memory device may be set, and for example, a level of a recovery voltage may be set based on a threshold voltage distribution of a ground selection line included in a GSL region. The threshold voltage distribution of the ground selection line included in the GSL region may be determined in operation S11, and a determination operation may be variously performed. For example, a level of a threshold voltage distribution may be determined based on certain coding information, or may be determined based on a verification voltage level used in a program process on a ground selection line, or various methods such as an operation of determining an on cell or an off cell through a read operation on a coded ground selection line may be applied.

In association with setting of a recovery voltage level, whether threshold voltage distributions of ground selection lines have a first distribution state may be determined in operation S12. The first distribution state may denote a state where a first threshold voltage level and a second threshold voltage level have a certain set value, and a second distribution state, which differs from the first distribution state, may denote a state where at least one of the first and second threshold voltage levels differs from the first distribution state. According to one or more embodiments, a level of a recovery voltage may be differently set based on a determination result of a distribution state, and for example, a recovery voltage having a first level may be set when a threshold voltage distribution of ground selection transistors corresponds to the first distribution state in operation S13, and a recovery voltage having a second level may be set when a threshold voltage distribution of ground selection transistors corresponds to the second distribution state in operation S14. For example, when a second threshold voltage level in the second distribution state is higher than a second threshold voltage level in the first distribution state, a recovery voltage may be controlled so that a level of a recovery voltage provided to a ground selection line in the second distribution state is higher than that of a recovery voltage in the first distribution state. Subsequently, as the memory device enters a recovery period, a recovery voltage having the set level may be provided to a ground selection line in operation S15.

Also, the memory device may enter a set-up period where a voltage provided to various lines of a cell block increases to a target level in operation S16. The memory device may control voltages provided to ground selection lines in the set-up period, and for example, may control an increase slope of each of voltages provided to ground selection lines.

In one or more embodiments, the memory device may control voltages provided to ground selection lines, based on determining a threshold voltage pattern of a plurality of ground selection transistors GST connected to a cell string. For example, in operation S17, the memory device may determine a ground selection transistor (for example, a first ground selection transistor) which has a second threshold voltage level Vth2 corresponding to a relatively high threshold voltage in a cell string, or is connected to a dummy line of a GSL region and is programmed at a relatively high threshold voltage level Vth_dum.

In controlling a voltage provided to a ground selection line connected to a first ground selection transistor, the memory device may determine a threshold voltage of a second ground selection transistor disposed on the first ground selection transistor in operation S18. For example, when the second ground selection transistor has a first threshold voltage level Vth1 corresponding to a relatively low threshold voltage, the memory device may set a slope of a voltage, provided to the first ground selection transistor, to a relatively large first value in operation S19, and thus, may decrease an HCI risk occurring in the second ground selection transistor. On the other hand, when the second ground selection transistor has a threshold voltage which is higher than the first threshold voltage level Vth1, the memory device may set a slope of a first voltage, provided to the first ground selection transistor, to a relatively small second value in operation S20.

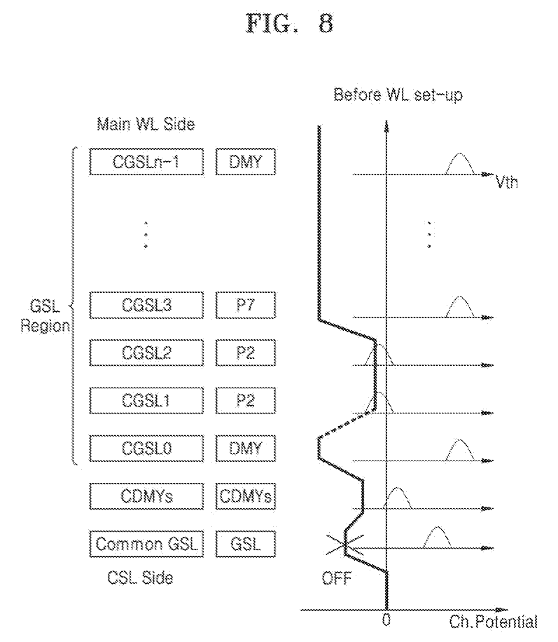

FIG. 8 is a diagram illustrating a channel potential of a cell string in association with the control of a voltage slope, according to one or more embodiments. In FIG. 8, a channel potential before setting voltages of word lines is illustrated.

Referring to FIG. 8, a cell string may include a plurality of main word lines, a GSL region, and additional word lines, and for example, first to nth ground selection lines CGSL0 to CGSLn-1, one or more common dummy lines DMYs, and a common GSL are illustrated. A case may be described where the GSL region includes an arbitrary number of ground selection lines, at least one ground selection line is used as a dummy line, and the first and nth ground selection lines CGSL0 and CGSLn-1 correspond to dummy lines.

In one cell string, a ground selection transistor connected to a ground selection line included in a coding region may be programmed with a first threshold voltage or a second threshold voltage, and for example, a case may be described where ground selection transistors connected to the second and third ground selection lines CGSL1 and CGSL2 have a threshold voltage corresponding to a second program state P2, and a ground selection transistor connected to the fourth ground selection line CGSL3 has a threshold voltage corresponding to a seventh program state P7. Also, a dummy line, the common dummy lines DMYs, and the common GSL each included in the GSL region may be programmed with one threshold voltage distribution, and for example, a case where the dummy line included in the GSL region is programmed with the threshold voltage corresponding to the seventh program state P7 may be described.

Before a voltage applied to word lines is set, a common ground selection transistor of the common GSL electrically connecting the word lines to a common source line may be in a turn-off state, and a channel potential may have a level associated with a threshold voltage of each of word lines (or transistors connected to word lines) of the cell string. For example, a potential of a channel corresponding to a word line having a low threshold voltage may have a relatively large value, and a potential of a channel corresponding to a word line having a high threshold voltage may have a relatively small value. Referring to FIG. 8, the first ground selection line CGSL0 may correspond to a dummy line programmed with a high threshold voltage and may thus be low in corresponding channel potential, and the second and third ground selection lines CGSL1 and CGSL2 may be connected to ground selection transistors programmed at a first threshold voltage level and may thus be relatively high in corresponding channel potential.

According to a channel potential characteristic illustrated in FIG. 8, a channel potential may rapidly increase in a direction toward the second and third ground selection lines CGSL1 and CGSL2 from the first ground selection line CGSL0, and a slope of the channel potential may have a large value. At this time, when electrons flow in through the common GSL as a set-up period starts, a risk caused by HCI may largely occur in the second and third ground selection lines CGSL1 and CGSL2, and a threshold voltage characteristic of ground selection transistors of the second and third ground selection lines CGSL1 and CGSL2 may be degraded. Accordingly, a method of reducing the HCI risk may be needed.

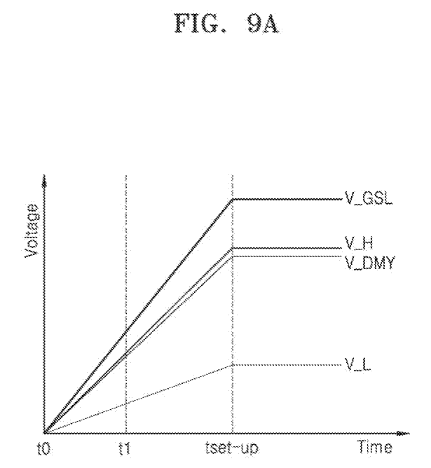

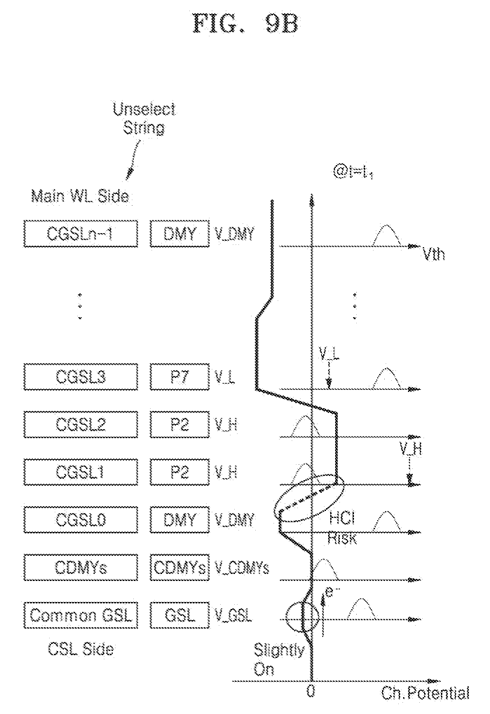

FIGS. 9A and 9B are diagrams illustrating a channel potential occurring in a set-up process when one or more embodiments is not applied.

Referring to FIG. 9A, a first voltage V_H or a second voltage V_L may be provided to a ground selection line included in a coding region in one cell string, and for example, the first voltage V_H may have a level which turns on all ground selection transistors programmed with first and second threshold voltages, and the second voltage V_L may have a level which turns off a ground selection transistor programmed with the second threshold voltage. Also, a voltage provided to a dummy line of the GSL region may be defined as a third voltage V_DMY, and a voltage provided to a common GSL may be defined as a fourth voltage V_GSL. Also, a voltage of an arbitrary level may be provided to common dummy lines outside the GSL region.

When one or more embodiments is not applied, a set-up period corresponding to voltages provided to word lines may be identically set. For example, the first voltage V_H and the third voltage V_DMY, which increase to the same target level, may be equal to each other in increase slope of a voltage. In one or more embodiments of FIG. 9A, a case may be described where a target level of the fourth voltage V_GSL is highest, and a target level of the second voltage V_L is lowest. Also, a time t0 may correspond to a time at which the set-up period starts, a time t1 may represent an arbitrary time after the set-up period starts, and voltages provided to word lines may have a level which is less than the target level. Also, a time test-up may correspond to a time at which the set-up period ends.

FIG. 9B illustrates a potential of a channel at a time t1 when one or more embodiments is not applied. For example, a case may be described where a cell string of FIG. 9B corresponds to a non-selection cell string, and thus, the first voltage V_H is applied to a ground selection transistor programmed at a first threshold voltage level, and the second voltage V_L is applied to a ground selection transistor programmed at a second threshold voltage level.

As a level of the fourth voltage V_GSL applied to the common GSL increases progressively, a ground selection transistor connected to the common GSL may be slightly turned on, and thus, electrons may flow into a channel of a cell block. Also, as described above, a threshold voltage level of a first ground selection line CGSL0 used as a dummy line may be high, and threshold voltage levels of second and third ground selection lines CGSL1 and CGSL2 thereon may be low, and thus, a channel potential may largely vary toward the second and third ground selection lines CGSL1 and CGSL2 from the first ground selection line CGSL0, and an HCI risk of the second and third ground selection lines CGSL1 and CGSL2 may increase.

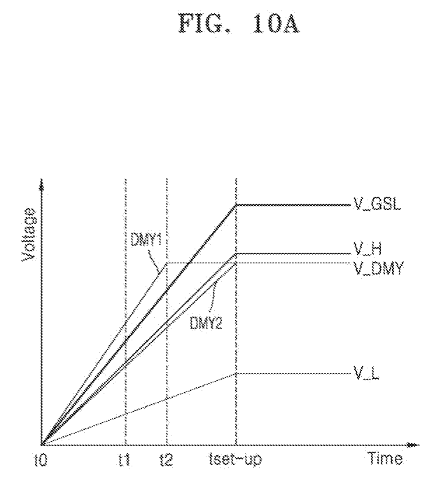

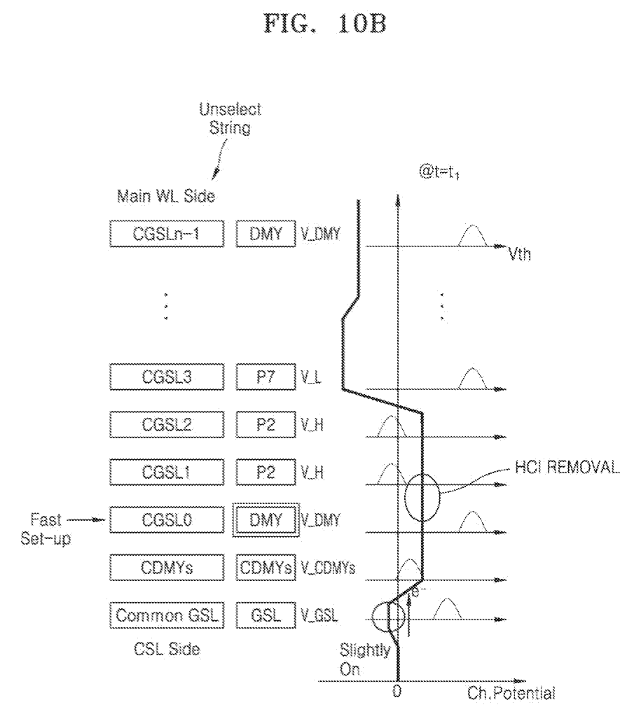

FIGS. 10A and 10B to 12 are diagrams illustrating a channel potential occurring in a set-up process when one or more embodiments is applied.

To decrease or remove the HCI risk, an increase slope of a voltage provided to at least one ground selection line may be controlled. For example, an increase slope of a voltage provided to at least one of a ground selection line which corresponds to a dummy line and is disposed in a lower portion of a GSL region and a ground selection line programmed with a second threshold voltage of a high level may be set to be large. For example, in one or more embodiments of FIG. 10A, a case is illustrated where a ground selection line programmed with a first threshold voltage of a low level is disposed on the dummy line, and thus, an increase slope of a third voltage V_DMY provided to the dummy line is set to be large.

The GSL region may include a plurality of dummy lines, and for example, with respect to a ground selection transistor programmed with the first threshold voltage, the GSL region may include a first dummy line disposed thereunder (or at a common source line side) and a second dummy line disposed thereon (or at a main word line side). In one or more embodiments, the increase slope of the third voltage V_DMY may be differently set based on positions at which dummy lines are disposed.

As illustrated in FIG. 10A, in a set-up period, a first voltage V_H, a second voltage V_L, and a fourth voltage V_GSL may vary in level so as to be equal to one or more embodiments illustrated in FIG. 9A. On the other hand, in association with the third voltage V_DMY provided to a dummy line, as a first dummy line DMY1 is disposed under a ground selection transistor programmed with the first threshold voltage, a fast set-up for quickly completing a set-up on a third voltage V_DMY provided to the first dummy line DMY1 may be applied, and thus, an increase slope thereof may be set to be greater than a third voltage V_DMY provided to the second dummy line DMY2. As illustrated in FIG. 10A, the third voltage V_DMY provided to the first dummy line DMY1 may have a level which is higher than that of the third voltage V_DMY provided to the second dummy line DMY2 at a time t1, and a time at which a set-up of the first dummy line DMY1 is completed may correspond to t2, and thus, the set-up may be earlier completed than the second dummy line DMY2.

Referring to FIG. 10B, as embodiments are applied, a channel potential may have a waveform which differs from that of a channel potential illustrated in FIG. 9B. For example, when a case is assumed where a first dummy line corresponds to a first ground selection line CGSL0, and second and third ground selection lines CGSL1 and CGSL2 thereon are programmed at a first threshold voltage level, a level of a third voltage V_DMY provided to a first dummy line at a time t1 in a set-up process may increase, and thus, a channel potential corresponding to the first dummy line may increase. For example, a channel potential corresponding to the first ground selection line CGSL0 may be disposed thereon and may have a level similar to that of a channel potential corresponding to the second and third ground selection lines CGSL1 and CGSL2 programmed with the first threshold voltage, and thus, an HCI risk occurring in the second and third ground selection lines CGSL1 and CGSL2 may decrease.

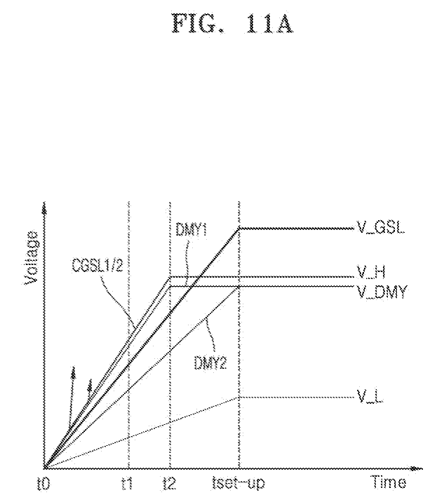

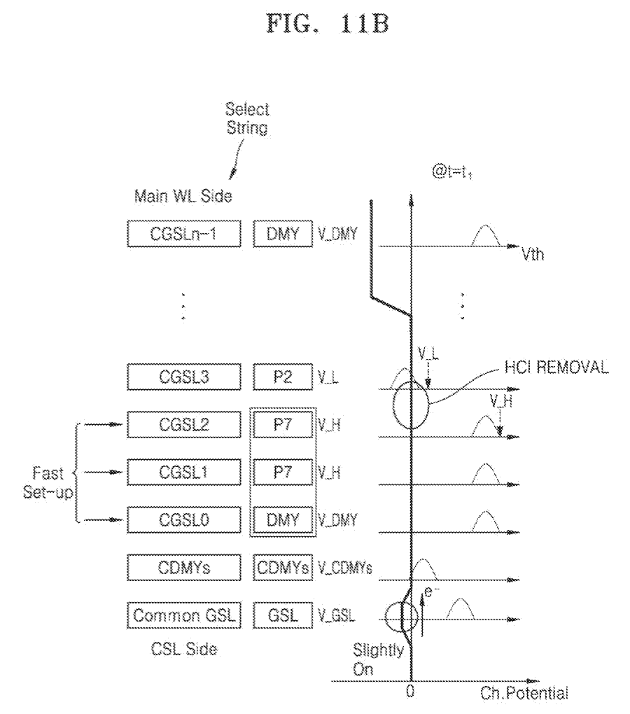

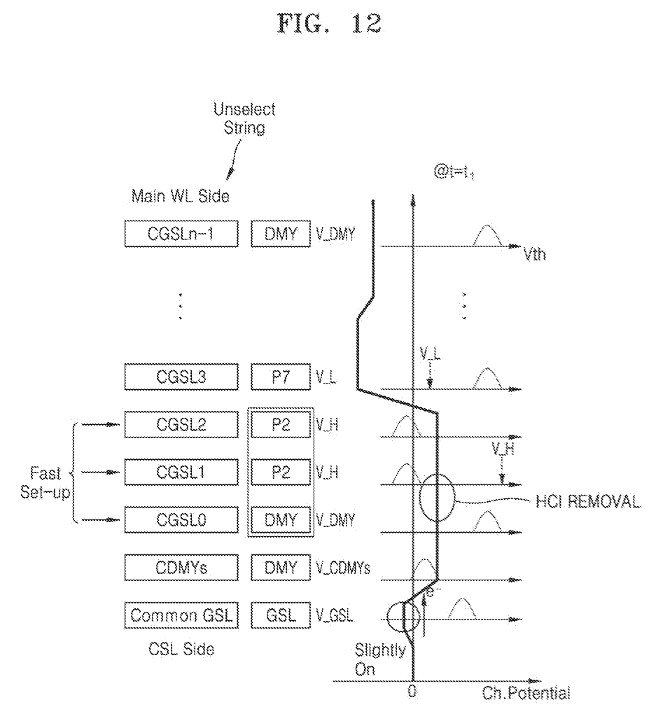

Furthermore, FIGS. 11A, 11B, and 12 illustrate an example which decreases an HCI risk occurring in all of a selection cell string and a non-selection cell string. For example, an example is illustrated where an increase slope of a voltage provided to at least one ground selection line of a coding region programmed with first and second threshold voltages in a GSL region. For example, an example may be described where slopes of voltages provided to a ground selection line of the coding region and a dummy line of the GSL region increase together.

Referring to FIG. 11A, an increase slope of a first voltage V_H provided to a ground selection line which is disposed at a common source line side in one cell string and is connected to a ground selection transistor which has a second threshold voltage may be set to be large. A case may be described where an increase slope of the first voltage V_H provided to second and third ground selection lines CGSL1 and CGSL2 is set to be large. In one or more embodiments of FIG. 11A, it is illustrated that the increase slope of the first voltage V_H is equal to an increase slope of a third voltage V_DMY provided to a first dummy line of the common source line side, but embodiments are not limited thereto and an increase slope may be variously set.

FIG. 11B illustrates a voltage provided to ground selection lines in a selection cell string and a channel potential at a time t1. Referring to FIGS. 11A and 11B, second and third ground selection lines CGSL1 and CGSL2 programmed with a second threshold voltage may be disposed on a first ground selection line CGSL0 corresponding to a first dummy line, and a fourth ground selection line CGSL3 programmed with a first threshold voltage may be disposed thereon. Also, a first voltage V_H may be provided to the second and third ground selection lines CGSL1 and CGSL2, and a second voltage V_L may be provided to the fourth ground selection line CGSL3.

As illustrated in FIG. 11B, before a set-up period starts, a channel potential corresponding to the first to third ground selection lines CGSL0 to CGSL2 may have a small value, and a channel potential corresponding to the fourth ground selection line CGSL3 may have a large value. Therefore, as the set-up period starts, electrons may flow into a channel through a slightly turned-on common ground selection transistor, and in a channel corresponding to the fourth ground selection line CGSL3, an HCI risk may increase based on an increase in potential variation.

According to one or more embodiments, as illustrated in FIG. 11B, as an increase slope of a level of each of the first voltage V_H and the third voltage V_DMY each provided to the first to third ground selection lines CGSL0 to CGSL2 is set to be large, a channel potential corresponding to the first to third ground selection lines CGSL0 to CGSL2 may increase, and thus, a level difference with a channel potential corresponding to the fourth ground selection line CGSL3 may be reduced. Accordingly, an HCI risk occurring in the fourth ground selection line CGSL3 in a selection cell string may be reduced.

FIG. 12 illustrates a channel potential of an unselected cell string when one or more embodiments illustrated in FIGS. 11A and 11B is applied. As word lines are disposed in a plurality of cell strings in common, the same voltages may be provided to word lines of a selection cell string and an unselected cell string, and thus, word lines illustrated in FIG. 12 may have the same level as those of word lines illustrated in FIGS. 11A and 11B.

As in one or more embodiments illustrated in FIGS. 11A and 11B, in a case where an increase slope of a third voltage V_DMY provided to a first ground selection line CGSL0 corresponding to a first dummy line increases, and an increase slope of a first voltage V_H provided to second and third ground selection lines CGSL1 and CGSL2 thereon increases, an HCI risk occurring in an unselected cell string may be reduced as illustrated in FIG. 12. For example, as illustrated in FIGS. 9A and 9B, the possibility that an HCI risk occurs in the second ground selection line CGSL1 due to a channel potential in an unselected cell string may be high, and according to one or more embodiments, an HCI risk occurring in the second ground selection line CGSL1 may decrease. That is, an increase slope of a voltage provided to a lower dummy line and at least one ground selection line thereon in a GSL region may be set to be large, and thus, an HCI risk occurring in a selection cell string and an unselected cell string may be reduced.

In one or more embodiments described above, a case is illustrated where an increase slope of a voltage increases on a dummy line disposed at a common source line side and two ground selection lines thereon, but one or more embodiments is not limited thereto. For example, a threshold voltage pattern may be variously set based on coding of the GSL region, and based on the number of ground selection transistors which have a second threshold voltage and are disposed on a dummy line of the common source line side in a certain cell string, an increase slope of a voltage level provided to a various number of ground selection lines may increase.

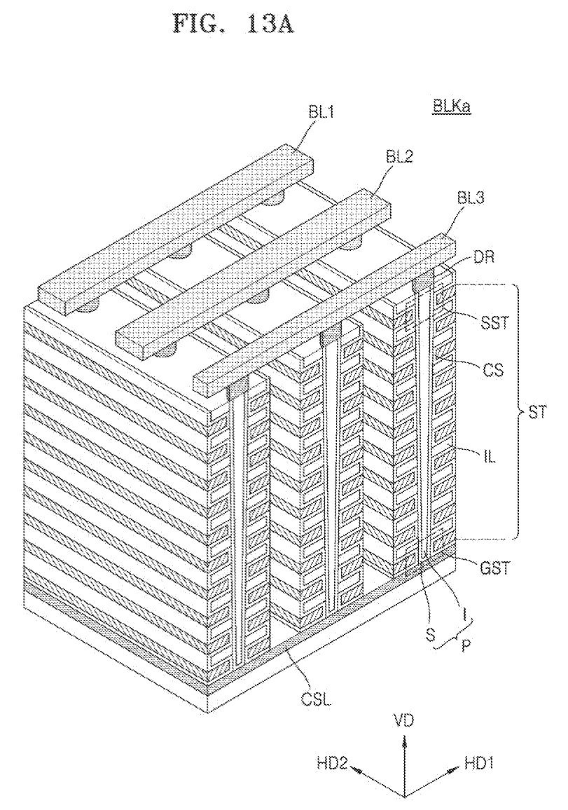

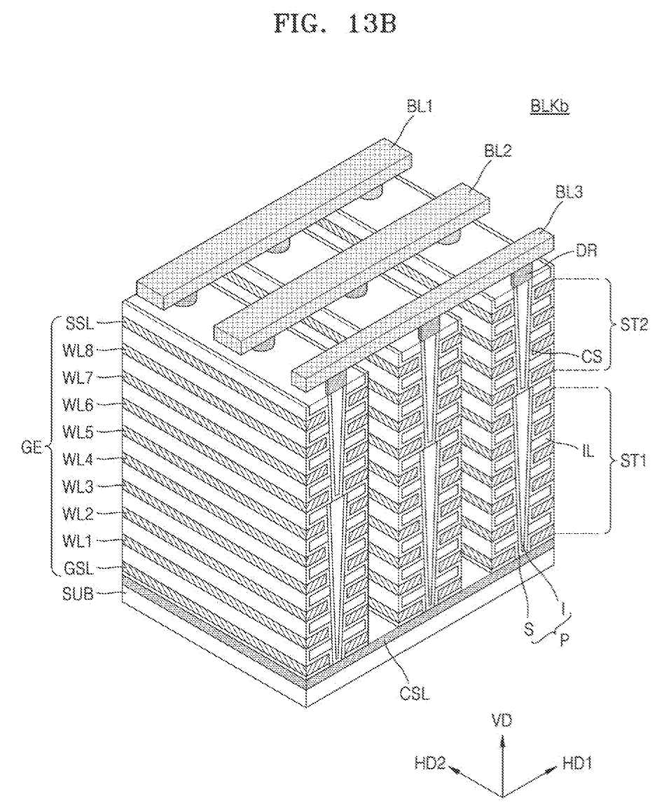

FIGS. 13A and 13B are perspective views illustrating a cell block according to one or more embodiments.

Referring to FIG. 13A, a cell block BLKa may correspond to one of the plurality of cell blocks BLK1 to BLKz of FIG. 3. The cell block BLKa may include a memory stack ST which extends in a vertical direction VD on a substrate SUB. For example, the cell block BLKa may include a single memory stack ST between the substrate SUB and bit lines BL1 to BL3. Common source lines CSL may be disposed in the substrate SUB, a plurality of insulation layers IL extending in a second horizontal direction HD2 may be sequentially provided in the vertical direction VD in a region of the substrate SUB between two adjacent common source lines CSL, and the insulation layers IL may be apart from each other by a certain distance in the vertical direction VD. A plurality of pillars P passing through the insulation layers IL in the vertical direction VD may be provided in a region of the substrate SUB between two adjacent common source lines CSL. A surface layer S of each of the pillars P may include a silicon material having a first type and may function as a channel region. Moreover, an inner layer I of each pillar P may include an air gap or an insulating material such as silicon oxide.

A charge storage layer CS may be provided along the insulation layers IL, the pillars P, and an exposed surface of the substrate SUB, in a region between two adjacent common source lines CSL. The charge storage layer CS may include a gate insulation layer, a charge trap layer, and a blocking insulation layer. For example, the charge storage layer CS may have an oxide-nitride-oxide (ONO) structure. Also, a gate electrode GE such as selection lines GSL and SSL and word lines WL1 to WL8 may be provided on an exposed surface of the charge storage layer CS, in a region between two adjacent common source lines CSL. Drains DR may be respectively provided on the plurality of pillars P. The bit lines BL1 to BL3, which extend in a first horizontal direction HD1 and are apart from one another by a certain distance in the second horizontal direction HD2, may be provided on the drains DR.

Referring to FIG. 13B, a cell block BLKb may correspond to one of the plurality of cell blocks BLK1 to BLKz of FIG. 3. Also, the cell block BLKb may correspond to a modification example of the cell block BLKa of FIG. 13A, and descriptions given above with reference to FIG. 13A may be applied to one or more embodiments. The cell block BLKb may include a first memory stack ST1 and a second memory stack ST2, which are stacked on the substrate SUB in the vertical direction VD. For example, the cell block BLKb may include two memory stacks (i.e., the first and second memory stacks ST1 and ST2) between the substrate SUB and bit lines BL1 to BL3, and thus, may have a multi-stack structure (for example, a 2-stack structure). In this case, lengths of the first and second memory stacks ST1 and ST2 in a vertical direction may differ. However, the disclosure is not limited thereto, and according to one or more embodiments, the cell block BLKb may include three or more memory stacks between the substrate SUB and the bit lines BL1 to BL3.

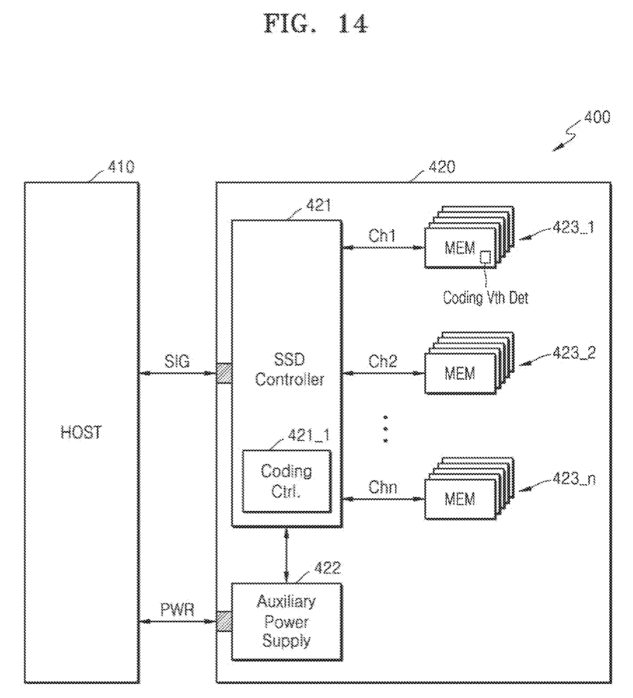

FIG. 14 is a block diagram illustrating a storage device to which a memory device according to one or more embodiments is applied. For example, the storage device of FIG. 14 may be an SSD device, and a system of FIG. 14 may be referred to as an SSD system 400.

Referring to FIG. 14, the SSD system 400 may include a host 410 and an SSD device 420. The SSD device 420 may transmit and receive a signal to and from the host 410 through a signal connector and may be supplied with power through a power connector. The SSD device 420 may include an SSD controller 421, an auxiliary power supply 422, and memory devices 423_1 to 423_n. The memory devices 423_1 to 423_n may each be a vertical stack-type NAND flash memory device. In this case, the SSD device 420 may be implemented by using one or more embodiments described above with reference to FIGS. 1 to 13. That is, each of the memory devices 423_1 to 423_n included in the SSD device 420 may include a plurality of cell blocks, and each of the cell blocks may include a GSL region including a plurality of ground selection lines.

The SSD controller 421 may include a coding controller 421_1, and the coding controller 421_1 may control an operation of programming threshold voltages of ground selection lines of the GSL region included in the memory devices 423_1-423_n according to one or more embodiments described above. For example, control information associated with coding of the GSL region may be stored in the SSD controller 421 or the memory devices 423_1-423_n, and the coding controller 421_1 may program each of the ground selection lines with a certain threshold voltage based on the control information.

Furthermore, according to embodiments, each of the memory devices 423_1 to 423_n may include a coding threshold voltage determiner and a voltage controller. For example, in a recovery operation on each of the memory devices 423_1 to 423_n, threshold voltage levels of the ground selection lines of the GSL region may be determined, and based on a result of level determination, a level of a recovery voltage provided to the ground selection lines may be controlled. Also, in a set-up period which sets word line voltages of each of the memory devices 423_1 to 423_n, a threshold voltage pattern of ground selection transistors of a cell string may be determined, and based on a determination result, an increase slope of a voltage provided to at least one ground selection line may be set to be large. For example, when a ground selection line programmed with a relatively high threshold voltage is disposed under a ground selection line programmed with a threshold voltage having a low level, an increase slope of a voltage provided to the ground selection line disposed thereunder may be set to be large.

Hereinabove, example embodiments have been described in the drawings and the specification. Embodiments have been described by using the terms described herein, but this has been merely used for describing the disclosure and has not been used for limiting a meaning or limiting the scope of the disclosure defined in the following claims. Therefore, it may be understood by those of ordinary skill in the art that various modifications and other equivalent embodiments may be implemented from the disclosure. Accordingly, the spirit and scope of the disclosure may be defined based on the spirit and scope of the following claims.

While embodiments of the disclosure have been particularly shown and described, it will be understood that various changes in form and details may be made therein without departing from the spirit and scope of the following claims.

What is claimed is:

1. A memory device comprising:
a memory cell array comprising a plurality of cell blocks, each of the plurality of cell blocks comprising:
a plurality of main word lines configured to be programmed with data, and
a ground selection line (GSL) region comprising a plurality of ground selection lines configured to be coded to be electrically separated on a plurality of cell strings;
a control logic configured to control a memory operation on the memory cell array and control a recovery operation of initializing lines in the cell blocks; and
a voltage generator configured to generate a recovery voltage provided to the plurality of ground selection lines in the recovery operation,
wherein the plurality of ground selection lines are configured to be programmed to have a first threshold voltage distribution at a first threshold voltage level and a second threshold voltage distribution at a second threshold voltage level, the second threshold voltage level being higher than the first threshold voltage level, and
wherein the control logic is further configured to control the voltage generator so that a level of the recovery voltage provided to a corresponding ground selection line increases as the second threshold voltage level increases.

2. The memory device of claim 1, wherein the control logic is further configured to:
set the recovery voltage to a first level, based on the first threshold voltage level corresponding to a first value, and the second threshold voltage level corresponding to a second value; and
set the recovery voltage to a second level lower than the first level, based on the first threshold voltage level corresponding to a third value less than the first value, and the second threshold voltage level corresponding to the second value.

3. The memory device of claim 1, wherein the control logic is further configured to:
set the recovery voltage to a first level, based on the first threshold voltage level corresponding to a first value, and the second threshold voltage level corresponding to a second value; and
set the recovery voltage to a second level lower than the first level, based on the first threshold voltage level corresponding to a third value less than the first value, and the second threshold voltage level corresponding to a fourth value less than the second value.

4. The memory device of claim 3, wherein a difference between the first level and the second value of the second threshold voltage level is less than a difference between the second level and the fourth value of the second threshold voltage level.

5. The memory device of claim 1, wherein the plurality of cell blocks comprise a first cell block and a second cell block, and a threshold voltage distribution of the ground selection lines of the first cell block differs from a threshold voltage distribution of the ground selection lines of the second cell block, and
wherein the control logic is further configured to set a level of the recovery voltage provided to the ground selection lines of the first cell block different from a level of the recovery voltage provided to the ground selection lines of the second cell block.

6. The memory device of claim 1, wherein a threshold voltage distribution of some ground selection lines of a first cell block of the plurality of cell blocks differs from a threshold voltage distribution of other ground selection lines, and
a level of the recovery voltage provided to the some ground selection lines of the first cell block differs from a level of the recovery voltage provided to the other ground selection lines.

7. The memory device of claim 1, wherein the GSL region further comprises a first ground selection line corresponding to a first dummy line,
wherein a first cell string of the plurality of cell strings comprises: a first dummy transistor connected to the first ground selection line and having a third threshold voltage level, and a ground selection transistor connected to a second ground selection line on the first ground selection line and having the first threshold voltage level, and
wherein the third threshold voltage level is higher than the first threshold voltage level.

8. The memory device of claim 7, wherein the control logic is further configured to, in a set-up process on the plurality of cell blocks, perform control so that an increase slope of a first voltage provided to the first ground selection line increases, and the first voltage reaches a target level earlier than a second voltage provided to the second ground selection line.

9. The memory device of claim 8, wherein the GSL region further comprises a third ground selection line corresponding to a second dummy line, and the third ground selection line is on the second ground selection line,
wherein the first cell string further comprises a second dummy transistor connected to the third ground selection line,
wherein a target level of the first voltage is equal to a target level of a third voltage provided to the third ground selection line, and
wherein the control logic is further configured to, in the set-up process, set the increase slope of the first voltage to be greater than an increase slope of the third voltage.

10. The memory device of claim 8, wherein the GSL region further comprises a third ground selection line between the first ground selection line and the second ground selection line, the first cell string further comprises a ground selection transistor connected to the third ground selection line and having the second threshold voltage level, and
in the set-up process, the control logic is configured to perform control so that an increase slope of a third voltage provided to the third ground selection line increases, and the third voltage reaches a target level earlier than the second voltage.

11. A memory device comprising:
a memory cell array comprising a plurality of cell blocks, each of the plurality of cell blocks comprising:
a plurality of main word lines configured to be programmed with data, and
a plurality of ground selection lines configured to be coded to be electrically separated on a plurality of cell strings; and
a control logic configured to control a memory operation on the memory cell array and control levels of voltages provided to the plurality of cell blocks,
wherein the plurality of ground selection lines comprise:
a first ground selection line corresponding to a first dummy line, and
a second ground selection line on the first ground selection line and configured to be programmed to have threshold voltage distributions based on the coding,
wherein the second ground selection line is configured to have a first threshold voltage distribution at a first threshold voltage level and a second threshold voltage distribution at a second threshold voltage level, and the first ground selection line is configured to have a third threshold voltage distribution,
wherein a first cell string of the plurality of cell strings comprises:
a first dummy transistor connected to the first ground selection line and configured to have a third threshold voltage level, and
a ground selection transistor connected to the second ground selection line and configured to have the first threshold voltage level, and
wherein the control logic is further configured to, in a set-up process on voltages provided to the plurality of cell blocks, perform control so that an increase slope of a first voltage provided to the first ground selection line increases, and the first voltage reaches a target level earlier than a second voltage provided to the second ground selection line.

12. The memory device of claim 11, wherein the plurality of ground selection lines further comprise a third ground selection line corresponding to a second dummy line and on the second ground selection line, and in the set-up process, a target level of a third voltage provided to the third ground selection line is configured to be equal to a target level of the first voltage, and
wherein the control logic is further configured to set an increase slope of the third voltage to be less than an increase slope of the first voltage in the set-up process, and perform control so that the first voltage reaches a target level earlier than the third voltage.

13. The memory device of claim 11, wherein the plurality of ground selection lines further comprise a third ground selection line between the first ground selection line and the second ground selection line,
wherein the first cell string further comprises a ground selection transistor connected to the third ground selection line and having the second threshold voltage level, and
wherein the control logic is further configured to, in the set-up process, perform control so that an increase slope of a third voltage provided to the third ground selection line increases, and the third voltage reaches a target level earlier than the second voltage.

14. The memory device of claim 13, wherein the first voltage and the third voltage are configured to have the same target level, and the control logic is further configured to set an increase slope of the first voltage and an increase slope of the third voltage to be equal in the set-up process.

15. The memory device of claim 13, wherein the first cell string corresponds to a non-selection string of the plurality of cell strings, and
wherein the control logic is further configured to provide the first voltage with increased increase slope and the third voltage with increased increase slope to a second cell string corresponding to a selection string of the plurality of cell strings.

16. A memory device comprising:
a cell block comprising a ground selection line (GSL) region comprising a plurality of ground selection lines configured to be coded to be electrically separated on a plurality of cell strings of the cell block;
a control logic configured to control a memory operation on the cell block and control a recovery operation of initializing lines in the cell block; and
a voltage generator configured to generate a recovery voltage provided to the plurality of ground selection lines in the recovery operation,
wherein the plurality of ground selection lines are configured to be programmed to have a first threshold voltage distribution at a first threshold voltage level and a second threshold voltage distribution at a second threshold voltage level, the second threshold voltage level being higher than the first threshold voltage level, and
wherein the control logic is further configured to control the voltage generator so that a level of the recovery voltage provided to a corresponding ground selection line increases as the second threshold voltage level increases.

17. The memory device of claim 16, wherein the control logic is further configured to:
set the recovery voltage to a first level, based on the first threshold voltage level corresponding to a first value, and the second threshold voltage level corresponding to a second value; and
set the recovery voltage to a second level lower than the first level, based on the first threshold voltage level corresponding to a third value less than the first value, and the second threshold voltage level corresponding to the second value.

18. The memory device of claim 16, wherein the control logic is further configured to:
set the recovery voltage to a first level, based on the first threshold voltage level corresponding to a first value, and the second threshold voltage level corresponding to a second value; and
set the recovery voltage to a second level lower than the first level, based on the first threshold voltage level corresponding to a third value less than the first value, and the second threshold voltage level corresponding to a fourth value less than the second value.

19. The memory device of claim 18, wherein a difference between the first level and the second value of the second threshold voltage level is less than a difference between the second level and the fourth value of the second threshold voltage level.

20. The memory device of claim 16, wherein the GSL region further comprises a first ground selection line corresponding to a first dummy line,
wherein a first cell string of the plurality of cell strings comprises: a first dummy transistor connected to the first ground selection line and having a third threshold voltage level, and a ground selection transistor connected to a second ground selection line on the first ground selection line and having the first threshold voltage level, and
wherein the third threshold voltage level is higher than the first threshold voltage level.
